(19) United States
(12) Patent Application Publication
(10) Pub. No.: US 2026/0123332 A1
(43) Pub. Date: Apr. 30, 2026

(54) SUBSTRATE PROCESSING APPARATUS AND SUBSTRATE PROCESSING METHOD

(71) Applicant: SEMES CO., LTD., Cheonan-si (KR)

(72) Inventors: Gu Won SEON, Seoul (KR); Yun Sang KIM, Seongnam-si (KR); Jae Seung YU, Seoul (KR); Dae Sung KIM, Cheonan-si (KR); Gyeong Won SONG, Cheonan-si (KR)

(73) Assignee: SEMES CO., LTD., Cheonan-si (KR)

(21) Appl. No.: 19/368,798

(22) Filed: Oct. 24, 2025

(30) Foreign Application Priority Data
Oct. 24, 2024 (KR) 10-2024-0146985

(51) Int. Cl. H01L 21/67; B05C 11/10; G03F 7/16

(52) U.S. Cl. CPC H10P 72/0448; B05C 11/1013; G03F 7/162

(57) ABSTRACT

Provided is an apparatus for processing a substrate, the apparatus including: a liquid processing chamber for processing a substrate; and a liquid supply unit for supplying a liquid to the substrate. The liquid supply unit includes: a storage assembly in which a liquid is stored; a liquid supply pipe for supplying the liquid in the storage assembly to the liquid processing chamber; and a trap tank installed in the liquid supply pipe. The storage assembly includes: a pack unit including an inner pack in which a liquid is stored and an outer pack provided to surround the inner pack; and a pressurization unit for pressurizing the inner pack, and the liquid supply pipe is coupled to the inner pack so that the liquid in the inner pack is transmitted to the trap tank by gravity. The inside of the inner pack is provided with vacuum, and the liquid does not directly contact gas, thereby preventing bubbles from being generated inside the liquid. In addition, it is possible to save energy by transmitting the liquid in the inner pack to the trap tank by gravity.

### CROSS-REFERENCE TO RELATED APPLICATION

This application claims priority to and the benefit of Korean Patent Application No. 10-2024-0146985 filed in the Korean Intellectual Property Office on Oct. 24, 2024, the entire contents of which are incorporated herein by reference.

### TECHNICAL FIELD

The present invention relates to a substrate processing apparatus and a substrate processing method, and more particularly, to a substrate processing apparatus and a substrate processing method of supplying a liquid to a substrate.

### BACKGROUND ART

In order to manufacture a semiconductor device, various processes, such as cleaning, deposition, photography, etching, and ion implantation, are performed. Among the processes, the photography process includes a coating process of forming a film by coating a surface of the substrate with a photosensitive liquid, such as photoresist, an exposure process that transfers a circuit pattern to a film formed on the substrate, and a developing process that selectively removes a film formed on the substrate in a region on which the exposure process has been performed or a region opposite to the region.

Typically, a device that performs a coating process supplies a liquid, such as photoresist, from a nozzle onto a rotating substrate to form a liquid film on the substrate. As illustrated in FIG. 1, when a liquid supply unit 5000 supplying a liquid to a nozzle supplies gas through a gas supply unit 5300 to a bottle 5100 where the photoresist is stored, the photoresist in a bottle 5100 is transmitted to the outside of the bottle 5100 through a liquid transmitting pipe 5500 by gas pressure. However, as the gas comes into direct contact with the photoresist stored in the bottle 5100, a large amount of bubbles are generated, and the bubble-containing photoresist is supplied to the substrate, thereby degrading the uniformity of the liquid thickness formed on the substrate.

In addition, since the general liquid supply unit 5000 has a structure in which the photoresist in the bottle 5100 is supplied by gas pressure, the photoresist in the bottle 5100 is not completely consumed and the bottle is replaced.

### SUMMARY OF THE INVENTION

The present invention has been made in an effort to provide a substrate processing apparatus and a substrate processing method capable of efficiently processing a substrate.

The present invention has also been made in an effort to provide a substrate processing apparatus and a substrate processing method that minimize bubbles from being generated in a liquid supplied to a substrate.

The present invention has also been made in an effort to provide a substrate processing apparatus and a substrate processing method capable of preventing a storage assembly from being replaced while a large amount of liquid remains in a storage assembly.

The present invention has also been made in an effort to provide a substrate processing apparatus and a substrate processing method that prevent denaturation of a liquid stored in a pack unit.

Effects of the present disclosure are not limited to those described above and effects not stated above will be clearly understood to those skilled in the art from the specification and the accompanying drawings.

An exemplary embodiment of the present disclosure, an apparatus for processing a substrate, the apparatus comprising: a liquid processing chamber for processing a substrate; a liquid supply unit for supplying a liquid to the substrate disposed in the liquid processing chamber; and a controller for controlling the liquid supply unit, wherein the liquid supply unit includes: a storage assembly in which a liquid is stored; a liquid supply pipe for supplying the liquid in the storage assembly to the liquid processing chamber; and a trap tank installed in the liquid supply pipe, the storage assembly includes: a pack unit having an inner pack in which a liquid is stored; and a pressurization unit for pressurizing the inner pack, and the liquid supply pipe may be coupled to the inner pack so that the liquid in the inner pack is discharged to the trap tank by gravity.

According to the exemplary embodiment of the present invention, wherein the controller controls the liquid supply unit so that the liquid in the inner pack is supplied to the liquid supply pipe by gravity when the amount of liquid remaining in the inner pack is greater than a set amount, and the pack unit may be pressurized by the pressurization unit in addition to gravity to supply the liquid in the inner pack to the liquid supply pipe when the amount of liquid remaining in the inner pack is less than the set amount.

According to the exemplary embodiment of the present invention, wherein the pack unit further includes an outer pack having an accommodation space for accommodating the inner pack, and the pressurization unit may be a gas supply unit for supplying gas to an outer space of the inner pack in the accommodation space.

According to the exemplary embodiment of the present invention, wherein the liquid supply unit further may includes a detector that directly or indirectly detects a state of a liquid amount stored in the inner pack.

According to the exemplary embodiment of the present invention, wherein the detector may be an optical sensor installed in the liquid supply pipe.

According to the exemplary embodiment of the present invention, wherein the storage assembly further includes a container having an inner space, and the pack unit may be provided to be coupled to and separated from the container.

According to the exemplary embodiment of the present invention, wherein the liquid supply pipe may be connected to a lower end of the pack unit and extends in a vertical direction.

According to the exemplary embodiment of the present invention, wherein the liquid supply unit includes a plurality of storage assemblies, and the plurality of storage assemblies may be provided so that a storage assembly selected from among the plurality of storage assemblies supplies the liquid to the trap tank.

According to the exemplary embodiment of the present invention, wherein the storage assembly further may includes a liquid level detection sensor that detects a liquid level of the liquid remaining in the inner pack.

According to the exemplary embodiment of the present invention, wherein the inner pack may be made of an acid-resistant material.

According to the exemplary embodiment of the present invention, wherein the outer pack may be coated to block light.

According to the exemplary embodiment of the present invention, wherein the gas may be inert gas.

An exemplary embodiment of the present disclosure, a method of processing a substrate, the method comprising: supplying a liquid in an inner pack to a substrate to process the substrate with the liquid, wherein the liquid in the inner pack is discharged from the inner pack by gravity, and then, by pressurizing the inner pack, the liquid in the inner pack may be discharged from the inner pack by the pressurization.

According to the exemplary embodiment of the present invention, wherein the liquid discharged from the inner pack is first supplied to a trap tank and then may supplied from the trap tank to the substrate.

According to the exemplary embodiment of the present invention, wherein the pressurization may be performed by supplying gas to a space between an outer pack surrounding the inner pack and the inner pack and pressurizing the inner pack with the gas.

According to the exemplary embodiment of the present invention, wherein when the liquid remaining in the inner pack is greater than a set amount, the liquid in the inner pack is discharged from the inner pack by gravity, and then, when the amount of the liquid remaining in the inner pack is less than the set amount, the inner pack may be pressurized to discharge the liquid in the inner pack from the inner pack by the pressurization.

According to the exemplary embodiment of the present invention, wherein the iquid may be photoresist.

According to the exemplary embodiment of the present invention, wherein the gas may be inert gas.

An exemplary embodiment of the present disclosure, an apparatus for processing a substrate, the apparatus comprising: a liquid processing chamber for processing a substrate; a liquid supply unit for supplying a resist liquid to the substrate disposed in the liquid processing chamber; and a controller for controlling the liquid supply unit, wherein the liquid supply unit includes: a storage assembly in which the resist liquid is stored; a liquid supply pipe for supplying the resist liquid in the storage assembly to the liquid processing chamber; and a trap tank installed in the liquid supply pipe, the storage assembly includes: a container having an inner space; an outer pack disposed in the inner space and having an accommodation space; an inner pack which is disposed in the accommodation space and in which the resist liquid is stored; and a gas supply unit for supplying gas to an outer space of the inner pack in the accommodation space, the liquid supply pipe is coupled to the inner pack so that the resist liquid in the inner pack is discharged to the trap tank by gravity, and the controller controls the liquid supply unit so that the resist liquid in the inner pack is supplied to the liquid supply pipe by gravity when the amount of resist liquid remaining in the inner pack is greater than a set amount, and the inner pack is pressurized by the gas supply unit in addition to gravity to supply the resist liquid in the inner pack to the liquid supply pipe when the amount of resist liquid remaining in the inner pack is less than the set amount.

According to the exemplary embodiment of the present invention, wherein the liquid supply unit includes a plurality of storage assemblies, and the plurality of storage assemblies may be provided so that a storage assembly selected from among the plurality of storage assemblies supplies the liquid to the trap tank.

According to the exemplary embodiment of the present invention, it is possible to improve substrate processing efficiency.

According to the exemplary embodiment of the present invention, it is possible to suppress bubble formation by preventing gas from directly contacting a liquid stored in a pack unit.

According to the exemplary embodiment of the present invention, it is possible to prevent a storage assembly from being replaced in a state in which a large amount of liquid remains in a storage assembly.

According to the exemplary embodiment of the present invention, it is possible to prevent denaturation of a liquid stored in a pack unit.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram illustrating an example of a general liquid supply unit for supplying a liquid to a nozzle.

FIG. 2 is a diagram schematically illustrating a substrate processing apparatus according to an exemplary embodiment of the present invention.

FIG. 3 is a diagram schematically illustrating one example of a liquid processing chamber of FIG. 2.

FIG. 4 is a diagram schematically illustrating an example of a storage assembly of FIG. 2.

FIG. 5 is a diagram schematically illustrating an exemplary embodiment of a pack unit of FIG. 4.

FIGS. 6 to 8 are diagrams schematically illustrating a liquid transmitting method of a storage assembly according to the exemplary embodiment.

FIG. 9 is a diagram schematically illustrating a structure of a liquid supply unit according to another exemplary embodiment.

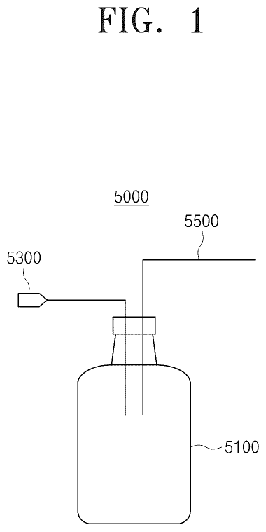

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

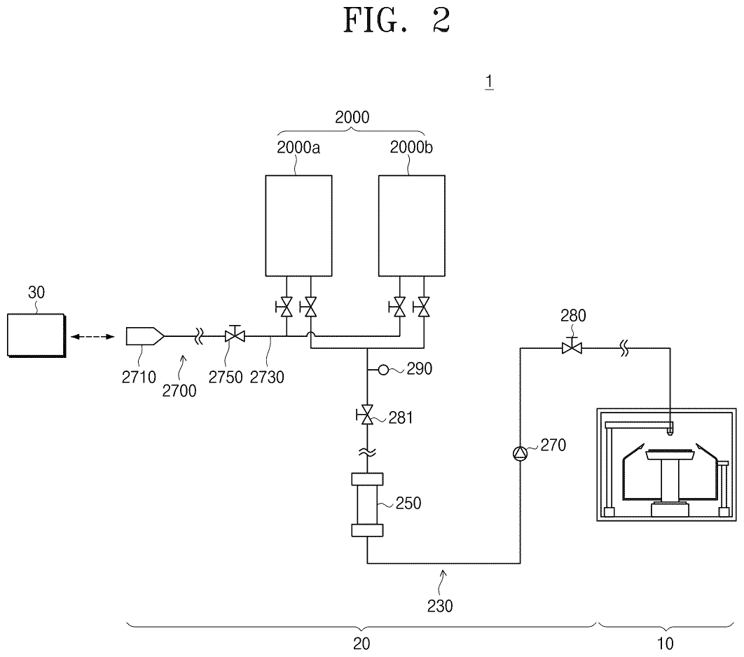

Hereinafter, an exemplary embodiment of the present invention will be described with reference to FIGS. 2 to 9.

In the following exemplary embodiment, the case where a substrate processing apparatus is an apparatus for performing a coating process of coating photoresist on a substrate will be described as an example. However, unlike this, the substrate processing apparatus may be an apparatus for coating an antireflection film, a protective film, or another kind of liquid onto a substrate.

FIG. 2 is a diagram schematically illustrating a substrate processing apparatus according to an exemplary embodiment of the present invention. Referring to FIG. 2, a substrate processing apparatus 1 includes a liquid processing chamber 10, a liquid supply unit 20, and a controller 30.

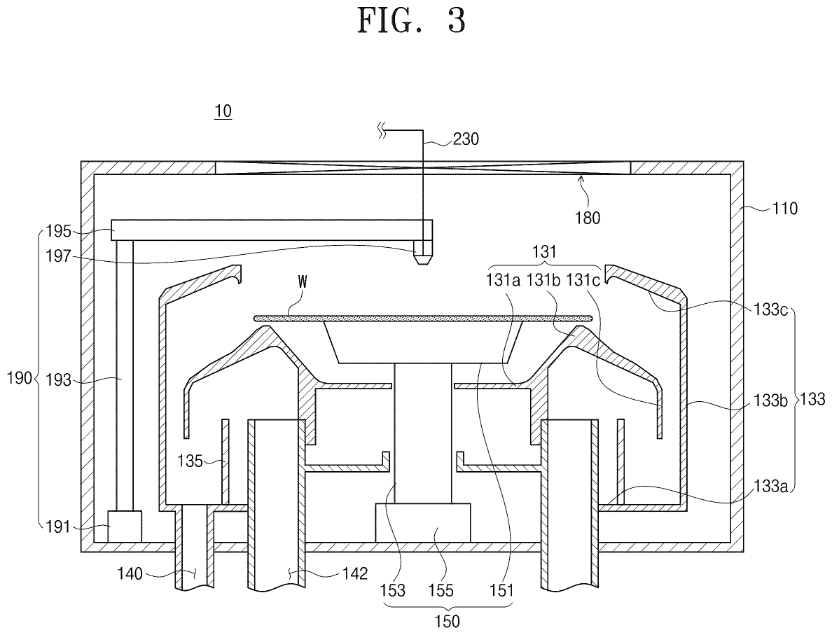

FIG. 3 is a diagram schematically illustrating one example of the liquid processing chamber of FIG. 2. Referring to FIG. 2, the liquid processing chamber 10 may include a housing 110, a cup 133, a support unit 150, a guide ring 131, an airflow supply unit 180, and a nozzle unit 190.

The housing 110 provides space therein. The housing 110 is provided in a generally rectangular parallelepiped shape. An opening (not illustrated) is formed at one side of the housing 110. The opening (not illustrated) functions as an entrance through which the substrate W is loaded into the inner space or the substrate W is unloaded from the inner space. Also, a door (not illustrated) is installed in an area adjacent to the entrance to selectively open and close the entrance. A door (not illustrated) blocks the entrance and seals the interior space from the outside while the processing process is performed on the substrate W loaded into the interior space. The cup 133, the support unit 150, the guide ring 131, and the nozzle unit 190 may be disposed in the interior space of the housing 110.

The cup 133 may be provided to surround the support unit 150 and the guide ring 131. The cup 133 may include a bottom wall 133a, a side wall 133b, and an upper wall 133c.

The bottom wall 133a may have a circular plate shape having a hollow. A discharge pipe 140 is connected to the bottom wall 133a. After processing the substrate W, the liquid scattered from the substrate W is discharged to the outside of the cup 133 through the discharge pipe 140.

An exhaust pipe 142 is connected to the bottom wall 133a. The exhaust pipe 142 is connected to the bottom wall 133a from the inner side than the exhaust pipe 140. Fume and airflow flowing in the cup 133 are exhausted to the outside of the cup 133 through the exhaust pipe.

The gas-liquid separation plate 135 may be installed on the bottom wall 133a. The gas-liquid separation plate 135 may be provided in an annular shape. The gas-liquid separation plate 135 is installed between the discharge pipe 140 and the exhaust pipe 142. The gas-liquid separation plate 135 prevents liquids used for processing the substrate W from flowing into the exhaust pipe 142.

The sidewall 133b may be provided in an annular ring shape surrounding the guide ring 131. The sidewall 133b may extend in a vertical direction from a side end of the bottom wall 133a.

The upper wall 133c may extend in a direction from an upper end of the side wall 133b toward a central axis of the outer cup 133. An inner surface of the upper wall 133c may extend to be inclined upward with respect to the ground as it approaches a central axis of the outer cup 133. The upper wall 133c may be provided to have a ring shape when viewed from above. While the processing of the substrate W is performed, the upper end of the upper wall 133c may be positioned to be higher than the upper surface of the substrate W supported by the support unit 150.

The support unit 150 supports and rotates the substrate W in a processing space. The support unit 150 may be a spin chuck that supports and rotates the substrate W. The support unit 150 may include a body 151, a support shaft 153, and a driving unit 155.

The guide ring 131 may have an inner wall 131a, an upper wall 131b, and an outer wall 131c. The inner wall 131a, the upper wall 131b, and the outer wall 131c may be combined with each other to provide a space in which the lower portion is open. The support shaft 153 of the support unit 150 may be surrounded by the inner wall 131a. The outer wall 131c may be combined with the cup 133 to form a discharge path through which the processing medium is discharged. The upper wall 131b may be provided to be inclined upward toward the outside from the inner wall 131a, and may then have a shape inclined downward toward the outer wall 131c.

The body 151 may have a top surface on which the substrate W is seated. The top surface of the body 151 may be provided in an approximately circular shape when viewed from the top. The top surface of the body 151 may have a diameter smaller than that of the substrate W. An adsorption hole (not illustrated) may be formed in the body 151. The adsorption hole (not illustrated) may vacuum-adsorb the substrate W seated on the top surface of the body 151.

The support shaft 153 is coupled with the body 151. The support shaft 153 may be coupled to a lower surface of the body 151. The longitudinal direction of the support shaft 153 may be provided in a vertical direction. The driving unit 155 may provide power for rotating the support shaft 153 with respect to a central axis thereof and for moving the support shaft 153 in a vertical direction. Accordingly, a relative height between the support unit 150 and the cup 133 may be adjusted.

An airflow supply unit 180 is installed on an upper end of the housing 110. The airflow supply unit 180 may supply airflow having a temperature and/or humidity adjusted to the interior space. The airflow supply unit 180 may be a Fan Filter Unit (FFU).

The nozzle unit 190 is provided in the housing 110. The nozzle unit 190 receives a liquid from the liquid supply unit 20 and supplies the liquid to the substrate W supported by the support unit 150. The nozzle unit 190 may include a driver 191, a support rod 193, an arm 195, and a nozzle 197.

The support rod 193 is located in the inner space of the housing 110. The support rod 193 is located on one side of the processing container 420 in the inner space. The support rod 193 may have a rod shape whose longitudinal direction faces a vertical direction.

The arm 195 is coupled to an upper end of the support rod 193. The arm 195 extends vertically from the longitudinal direction of the support rod 193. The nozzle 197 may be fixedly coupled to the end of the arm 195.

The driver 191 is coupled with the support rod 193. The driver 191 may be disposed on the bottom surface of the housing 110. The driver 191 provides driving force for rotating the support rod 193. The driver 191 may be provided as a motor.

The liquid supply unit 20 supplies photoresist to the nozzle 197 provided in the liquid processing chamber 10.

Referring to FIG. 2, the liquid supply unit 20 may include a storage assembly 2000, a liquid supply pipe 230, a trap tank 250, and a detector 290.

The storage assembly 2000 stores photoresist. A plurality of storage assemblies 2000a and 2000b may be provided. For example, the storage assemblies 2000a and 2000b may include a first storage assembly 2000a and a second storage assembly 2000b. Accordingly, the liquid may be first supplied from the first storage assembly 2000a to the trap tank 250 described later, and when the internal liquid of the first storage assembly 2000a is all exhausted, the liquid may be supplied from the second storage assembly 2000b to the trap tank 250. While the liquid is supplied from the second storage assembly 2000b, a pack unit 2300 in the first storage assembly 2000a may be replaced. The first storage assembly 2000a and the second storage assembly 2000b have the same or similar structures.

The liquid supply pipe 230 may supply the liquid in the storage assembly 2000 to the liquid processing chamber 10. A trap tank 250, a pump 270, and valves 281 and 283 to be described later may be installed in the liquid supply pipe 230.

The trap tank 250 may temporarily store the photoresist supplied from the storage assembly 2000. A liquid level detection sensor is installed on one side of the trap tank 250 to detect the liquid level of the photoresist and makes the liquid be continuously filled to an appropriate liquid level.

The pump 270 provides a flow pressure for flowing the photoresist stored in the trap tank 250 into the liquid processing chamber 10. The pump 270 may be installed on the downstream side of the liquid supply pipe 230 relative to the trap tank 250.

The valves 281 and 283 may be on/off valves. A flow rate control valve may be optionally further provided. Whether or not to supply photoresist from the storage assembly 2000 to the trap tank 250 by opening and closing the first valve 281 and the amount of photoresist supplied are determined. Whether or not to supply photoresist supplied to a processing space of the liquid processing chamber 10 by opening and closing the second valve 281 and the amount of photoresist supplied are determined. The first valve 281 may be installed on the upstream side of the liquid supply pipe 230 relative to the trap tank 250, and the second valve 283 may be installed the downstream side of the liquid supply pipe 230 relative to the pump 270.

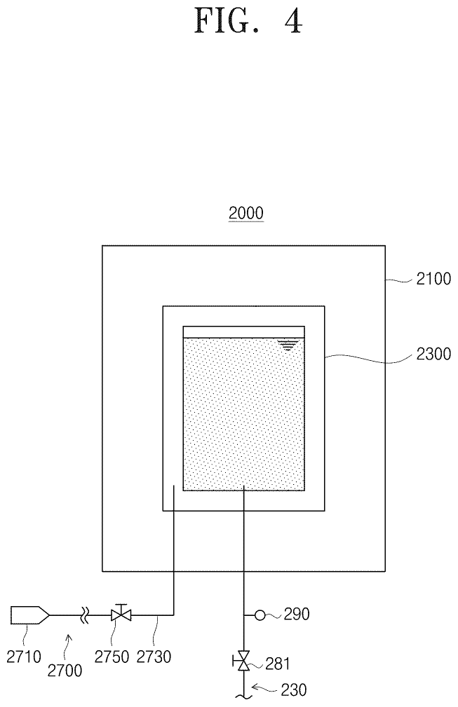

FIG. 4 is a diagram schematically illustrating an example of the storage assembly of FIG. 2.

Referring to FIG. 4, the storage assembly 2000 may include a container 2100, a pack unit 2300, and a gas supply unit 2700.

The container 2100 may be provided in a generally rectangular parallelepiped shape. An inner space is formed inside the container 2100. The pack unit 2300 is located in the inner space of the container 2100. A hole through which the liquid supply pipe 230 and the gas supply pipe 2730 may be connected is provided on the lower end surface of the container 2100.

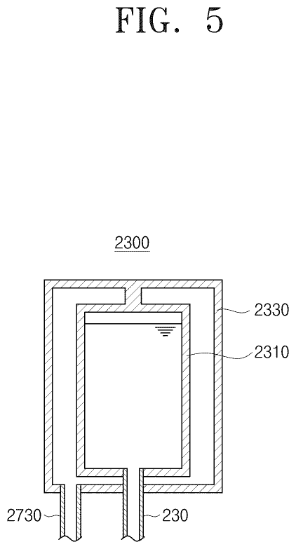

FIG. 5 is a diagram schematically illustrating an exemplary embodiment of the pack unit of FIG. 4. Referring to FIG. 5, the pack unit 2300 includes an inner pack 2310 and an outer pack 2330.

Photoresist is stored in the inner pack 2310. The inner pack 2310 may be made of a material that prevents denaturation of the photoresist stored therein. The inner pack 2310 may be made of an acid-resistant material. According to an example, the inner pack 2310 may be polytetrafluoroethylene (PTFE).

The inside of the inner pack 2310 may be provided in a vacuum state.

A liquid level detection sensor 2313 may be installed in the inner pack 2310 to detect the liquid level of the photoresist remaining therein. The liquid level detection sensor 2313 may transmit a replacement signal of the pack unit 2300 to the controller 30 when the photoresist remaining in the inner pack 2310 falls below a predetermined height.

The outer pack 2330 has an accommodation space for accommodating the inner pack 2310. The outer pack 2330 may be light-blocking coated to block light. As an example, the outer pack 2330 may be light blocking coated to block light in a wavelength band that reacts with the photoresist.

Referring back to FIG. 4, the pack unit 2300 is provided to be coupled to and separated from the container 2100. Accordingly, when the photoresist in the inner pack 2310 falls below a predetermined amount, the pack unit 2300 may be separated from the container 2100, and then the used pack unit 2300 may be removed and the new pack unit 2300 may be coupled to the container 2100.

According to an example, a cap that is coupled to and separated from the container 2100 may be provided at a lower end of the container 2100, and the pack unit 2300 may be provided detachably to the cap. A thread is provided on the outer circumferential surface of the cap, and a protrusion penetrating in a vertical direction is provided in the lower end surface of the container 2100 and a thread corresponding to the thread of the cap is provided to the inner circumferential surface of the protrusion, so that the cap may be coupled to the container 2100 while rotating the cap in a clockwise or counterclockwise direction, and separated from the container 2100 while rotating the cap in the opposite direction. However, the present invention is not limited thereto, and the pack unit 2300 may be coupled to and separated from the container 2100 by various known methods.

The gas supply unit 2700 may supply gas to the pack unit 2300. The gas may be inert gas. According to an example, the gas may be nitrogen gas (N₂)

The gas supply unit 2700 may include a gas supply source 2710 and a gas supply pipe 2730. Gas is stored in the gas supply source 2710. The gas supply pipe 2730 supplies the gas stored in the gas supply source 2710 to the outer space of the inner pack 2310 in the accommodation space of the outer pack 2330. The gas supply pipe 2730 may be provided with an opening/closing valve 2750 that opens and closes the inner passage thereof.

Referring to FIG. 2, the inner pack 2310 storing the photoresist is located above the trap tank 250, and the liquid supply pipe 230 is connected to the trap tank 250 by vertically extending downward from the lower end of the inner pack 2310. Accordingly, when there is a large amount of remaining photoresists in the inner pack 2310, the photoresist inside the inner pack 2310 may be supplied to the trap tank 250 by gravity without supplying separate energy.

The detector 290 directly or indirectly detects the state of the photoresist amount stored in the inner pack 2310. According to an example, the detector 290 may be installed in the liquid supply pipe 230. The detector 290 may be installed on the upstream side of the trap tank 250 in the liquid supply pipe 230. The detector 290 may detect the amount of photoresist flowing in the liquid supply pipe 230 and transmit the detected signal to the controller 30 to be described later. According to an example, the detector 290 is an optical sensor, and may detect whether there is an empty space between the liquid supply pipe 230 and the flowing photoresist, and transmit the detected signal to the controller 30.

The controller 30 may control the liquid supply unit 20 and the substrate processing apparatus 1 including the same so as to perform a substrate processing method described below. The controller 30 may control the storage assembly 2000 to supply the photoresist in the inner pack 2310 to the trap tank 250 by gravity without supplying separate energy when the photoresist remaining in the inner pack 2310 is larger than a set amount, and to supply gas by the gas supply unit 2700 to pressurize the inner pack 2310 when the photoresist remaining in the inner pack 2310 is less than the set amount.

As an example, the controller 30 receives a signal detected from the detector 290. When there is no empty space between the liquid supply pipe 230 and the flowing photoresist, the controller 30 controls the photoresist in the inner pack 2310 to be supplied to the trap tank 250 by gravity without supplying separate energy. When an empty space is detected between the liquid supply pipe 230 and the flowing photoresist, the controller 30 supplies gas from the gas supply unit 2700 to the outer space of the inner pack 2310 in the accommodation space of the outer pack 2330 to pressurize the inner pack 2310. Accordingly, energy may be saved compared to the existing method, and the liquid may be efficiently supplied even when the remaining amount of the liquid in the inner pack 2310 is small.

Furthermore, since the inside of the inner pack 2310 is provided in a vacuum state, and the inner pack 2310 is pressurized by gas from the outside, the photoresist stored in the inner pack 2310 has no contact with the gas. Therefore, it is possible to prevent bubbles from being generated from the photoresist.

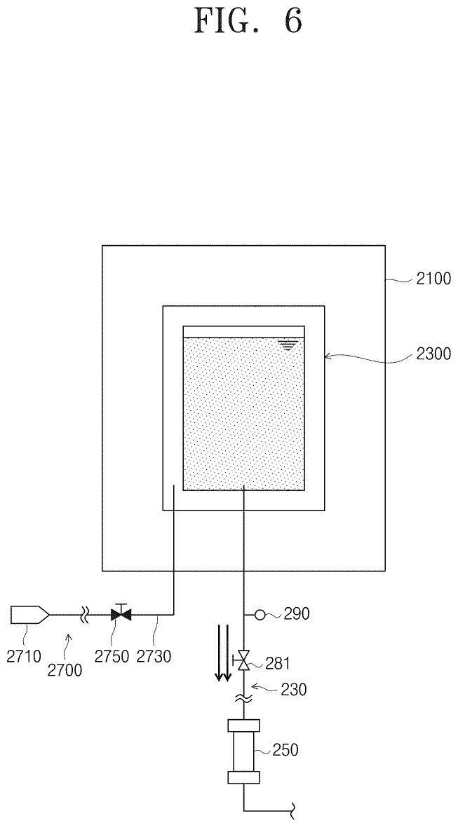

FIGS. 6 to 8 are diagrams schematically illustrating a liquid transmitting method of the storage assembly according to the exemplary embodiment. In FIGS. 6 to 8, the valve with the filled inside is in a closed state for preventing the fluid from flowing, and the valve with an empty inside is in an open state for allowing the fluid to flow. In addition, a dotted arrow indicates the flow direction of the inert gas, a solid arrow indicates the flow direction of the photoresist, the detector with the empty space indicates the case where the empty space is not detected, and the detector with the filled inside indicates the case where the empty space is detected.

Referring to FIG. 6, the first valve 281 of the liquid supply pipe 230 is initially opened, and the photoresist in the inner pack 2310 is discharged to the trap tank 250 through the liquid supply pipe 230 by gravity. In this case, the opening/closing valve 2750 in the gas supply pipe 2730 is closed.

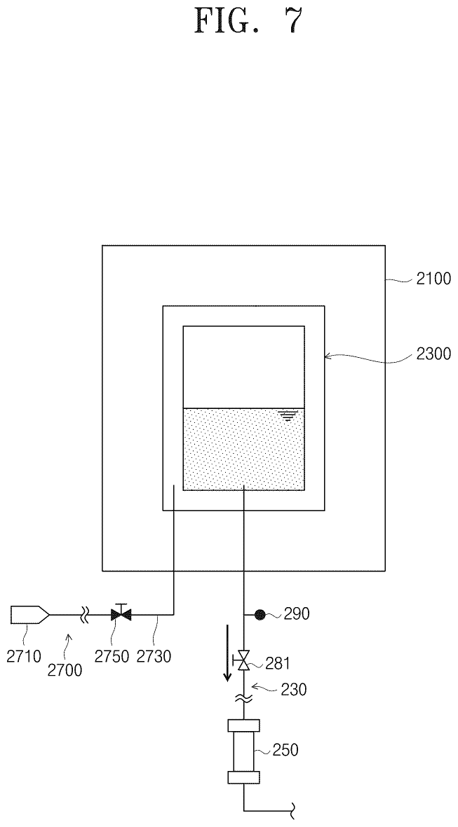

Then, as illustrated in FIG. 7, when the photoresist remaining in the inner pack 2310 decreases, the amount of photoresist flowing through the liquid supply pipe 230 decreases, and an empty space is detected between the liquid supply pipe 230 and the flowing photoresist by the detector 290.

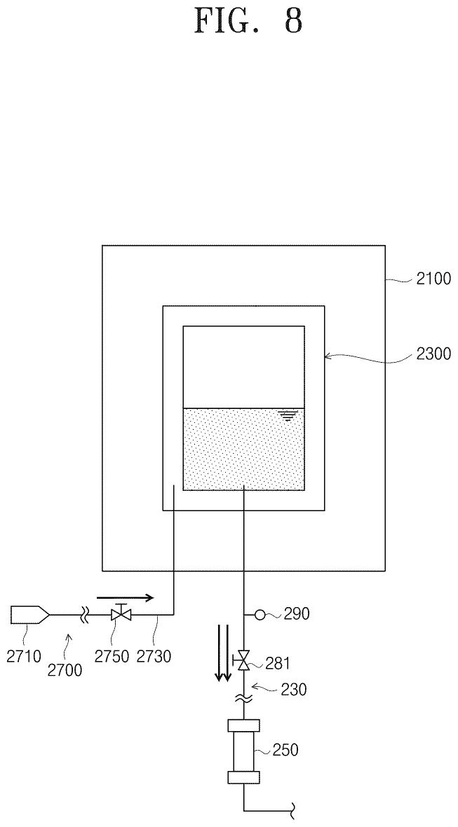

Thereafter, as illustrated in FIG. 8, the opening/closing valve 2750 in the gas supply pipe is opened to supply inert gas to the outer space of the inner pack 2310 in the accommodation space of the outer pack 2330 to pressurize the inner pack 2310. Accordingly, in FIG. 6, the same amount of photoresist as the amount of photoresist supplied through the liquid supply pipe 230 may be supplied to the trap tank 250.

When the controller 30 receives the replacement signal of the pack unit 2300 from the liquid level detection sensor 2313, the controller 30 transmits the replacement signal to a user. The controller 30 may visually display a replacement notification message on a display screen, and may audibly transmit the signal through a connected speaker. In addition, the replacement signal may be transmitted to the user in other known ways.

The user may receive the replacement signal and separate the pack unit 2300 from the container 2100, and couple the new pack unit 2300 to the container 2100 to replace the pack unit 2300.

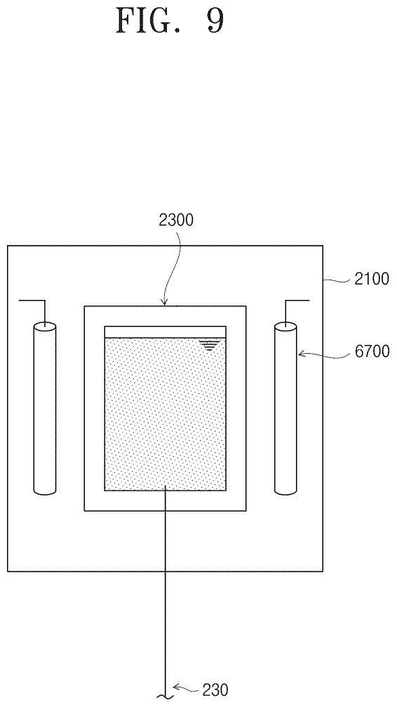

In the above-described exemplary embodiment of FIG. 4, the present invention has been described based on the case in which the gas supply unit 2700 is provided as the pressurization unit as an example. However, the present invention is not limited thereto, and as illustrated in FIG. 9, a pair of roller members 6700 may be provided as the pressurization unit. The roller member 6700 may pressurize the pack unit 2300 by moving horizontally in a left and right direction, and may rotate while being in contact with the pack unit 2300 to pressurize the pack unit 2300.

In the above-described exemplary embodiment of FIG. 2, the present invention has been described based on the case where the detector 290 is provided to the liquid supply pipe 230 as an example. However, the present invention is not limited thereto, and the detector 290 may be installed in the inner pack 2310 to directly detect the state of the liquid amount stored in the inner pack.

In the above-described exemplary embodiment of FIG. 4, the present invention has been described based on the case where the liquid level sensor 2313 is installed in the inner pack 2310 as an example. However, unlike this, the liquid level detection sensor 2313 may be installed in the container 2100 or the outer pack 2330 to detect the level of liquid remaining in the inner pack 2310.

In the above-described exemplary embodiment of FIG. 2, the present invention has been described based on the case where a plurality of storage assemblies 2000 is provided as an example. However, the present invention is not limited thereto, and a single storage assembly 2000 may be provided to store a liquid.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a liquid processing chamber for processing a substrate;
a liquid supply unit for supplying a liquid to the substrate disposed in the liquid processing chamber; and
a controller for controlling the liquid supply unit,
wherein the liquid supply unit includes:
a storage assembly in which a liquid is stored;
a liquid supply pipe for supplying the liquid in the storage assembly to the liquid processing chamber; and
a trap tank installed in the liquid supply pipe,
the storage assembly includes:
a pack unit having an inner pack in which a liquid is stored; and
a pressurization unit for pressurizing the inner pack, and
the liquid supply pipe is coupled to the inner pack so that the liquid in the inner pack is discharged to the trap tank by gravity.

2. The apparatus of claim 1, wherein the controller controls the liquid supply unit so that the liquid in the inner pack is supplied to the liquid supply pipe by gravity when the amount of liquid remaining in the inner pack is greater than a set amount, and the pack unit is pressurized by the pressurization unit in addition to gravity to supply the liquid in the inner pack to the liquid supply pipe when the amount of liquid remaining in the inner pack is less than the set amount.

3. The apparatus of claim 2, wherein the pack unit further includes an outer pack having an accommodation space for accommodating the inner pack, and
the pressurization unit is a gas supply unit for supplying gas to an outer space of the inner pack in the accommodation space.

4. The apparatus of claim 1, wherein the liquid supply unit further includes a detector that directly or indirectly detects a state of a liquid amount stored in the inner pack.

5. The apparatus of claim 4, wherein the detector is an optical sensor installed in the liquid supply pipe.

6. The apparatus of claim 1, wherein the storage assembly further includes a container having an inner space, and
the pack unit is provided to be coupled to and separated from the container.

7. The apparatus of claim 1, wherein the liquid supply pipe is connected to a lower end of the pack unit and extends in a vertical direction.

8. The apparatus of claim 1, wherein the liquid supply unit includes a plurality of storage assemblies, and
the plurality of storage assemblies is provided so that a storage assembly selected from among the plurality of storage assemblies supplies the liquid to the trap tank.

9. The apparatus of claim 1, wherein the storage assembly further includes a liquid level detection sensor that detects a level of the liquid remaining in the inner pack.

10. The apparatus of claim 1, wherein the inner pack is made of an acid-resistant material.

11. The apparatus of claim 3, wherein the outer pack is coated to block light.

12. The apparatus of claim 3, wherein the gas is inert gas.

13-18. (canceled)

19. An apparatus for processing a substrate, the apparatus comprising:
a liquid processing chamber for processing a substrate;
a liquid supply unit for supplying a resist liquid to the substrate disposed in the liquid processing chamber; and
a controller for controlling the liquid supply unit,
wherein the liquid supply unit includes:
a storage assembly in which the resist liquid is stored;
a liquid supply pipe for supplying the resist liquid in the storage assembly to the liquid processing chamber; and
a trap tank installed in the liquid supply pipe,
the storage assembly includes:
a container having an inner space;
an outer pack disposed in the inner space and having an accommodation space;
an inner pack which is disposed in the accommodation space and in which the resist liquid is stored; and
a gas supply unit for supplying gas to an outer space of the inner pack in the accommodation space,
the liquid supply pipe is coupled to the inner pack so that the resist liquid in the inner pack is discharged to the trap tank by gravity, and
the controller controls the liquid supply unit so that the resist liquid in the inner pack is supplied to the liquid supply pipe by gravity when the amount of resist liquid remaining in the inner pack is greater than a set amount, and the inner pack is pressurized by the gas supply unit in addition to gravity to supply the resist liquid in the inner pack to the liquid supply pipe when the amount of resist liquid remaining in the inner pack is less than the set amount.

20. The apparatus of claim 19, wherein the liquid supply unit includes a plurality of storage assemblies, and
the plurality of storage assemblies is provided so that a storage assembly selected from among the plurality of storage assemblies supplies the liquid to the trap tank.
